(19) United States
(12) Patent Application Publication
(10) Pub. No.: US 2008/0127887 A1
(43) Pub. Date: Jun. 5, 2008

(54) VERTICALLY MOUNTED ROTARY CATHODES IN SPUTTERING SYSTEM ON ELEVATED RAILS

(75) Inventors: Samuel Leung, San Jose, CA (US); Andreas Geiss, Hanau (DE); Toshio Kiyotake, Kobe (JP); Erkan Koparal, Nidderau (DE); Jose Albor, Santa Clara, CA (US); William Allan Bagley, Tokyo (JP)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 11/565,968

(22) Filed: Dec. 1, 2006

(51) Int. Cl. C23C 14/00

(52) U.S. Cl. 118/50.1

(57) ABSTRACT

The present invention generally comprises a physical vapor deposition (PVD) system having separate susceptor, cathode, and lid sections in which each section is on a rail that elevates the sections off the ground. The cathode section may comprise a plurality of rotatable cathodes that lie in a plane such that the axis of rotation for the rotary cathodes is perpendicular to the ground. The lid section and the cathode section may be moved on the rails to open the cathode section for servicing. Of the plurality of rotatable cathodes, the cathodes corresponding to the center of the substrate upon which material will be deposited are spaced a greater distance from the substrate than rotatable cathodes corresponding to the edge of the substrate.

### BACKGROUND OF THE INVENTION

1. Field of the Invention

Embodiments of the present invention generally relate to rotary cathodes, vertically mounted in a sputtering system.

2. Description of the Related Art

Physical Vapor Deposition (PVD) using a magnetron is one method of depositing material onto a substrate. During a PVD process a target may be electrically biased so that ions generated in a process region can bombard the target surface with sufficient energy to dislodge atoms from the target. The process of biasing a target to cause the generation of a plasma that causes ions to bombard and remove atoms from the target surface is commonly called sputtering. The sputtered atoms travel generally toward the substrate being sputter coated, and the sputtered atoms are deposited on the substrate. Alternatively, the atoms react with a gas in the plasma, for example, nitrogen, to reactively deposit a compound on the substrate. Reactive sputtering is often used to form thin barrier and nucleation layers of titanium nitride or tantalum nitride on the substrate.

Direct current (DC) sputtering and alternating current (AC) sputtering are forms of sputtering in which the target is biased to attract ions towards the target. The target may be biased to a negative bias in the range of about −100 to −600 V to attract positive ions of the working gas (i.e., argon) toward the target to sputter the atoms. Usually, the sides of the sputter chamber are covered with a shield to protect the chamber walls from sputter deposition. The shield may be electrically grounded and thus provide an anode in opposition to the target cathode to capacitively couple the target power to the plasma generated in the sputter chamber.

Large area sputtering targets are necessary for depositing material onto large area substrates such as flat panel display substrates, solar panel substrates, and other large area substrates. As the size of the substrate increases, so must the size of the sputtering target. Achieving uniform deposition on the large area substrate while also efficiently utilizing the sputtering target can be challenging.

It would be beneficial to produce large area sputtering targets suitable for depositing material onto large area substrates. It would also be beneficial if the large area sputtering target could have as uniform of an erosion profile as possible to reduce the amount of wasted target material. Therefore, there is a need in the art for large area sputtering targets.

### SUMMARY OF THE INVENTION

The present invention generally comprises a PVD system having separate susceptor, cathode, and lid sections in which each section is on a rail that elevates the sections off the ground. The cathode section may comprise a plurality of rotatable cathodes that lie in a plane such that the axis of rotation for the rotary cathodes is perpendicular to the ground. The lid section and the cathode section may be moved on the rails to open the cathode section for servicing. Of the plurality of rotatable cathodes, the cathodes corresponding to the center of the substrate upon which material will be deposited are spaced a greater distance from the substrate than rotatable cathodes corresponding to the edge of the substrate.

In one embodiment, an apparatus is disclosed. The apparatus comprises a sputtering chamber having a susceptor section, a cathode section, and a lid section. The susceptor section may comprise a susceptor movable between a position oriented substantially parallel to ground and a position substantially perpendicular to the ground. The cathode section may comprise a plurality of rotary cathodes oriented substantially perpendicular relative to the ground.

In another embodiment, an apparatus is disclosed. The apparatus comprises a loading station oriented to receive a substrate oriented substantially perpendicular relative to ground and a sputtering chamber. The sputtering chamber comprises a susceptor section having a susceptor, a cathode section having a plurality of rotary cathodes oriented substantially perpendicular relative to the ground. The lid section may be movable between a position coupled with the cathode section and another position. The cathode section is movable between a position coupled with the susceptor section and another position, and a lid section having a lid.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a perspective view of a sputtering system 100 according to one embodiment of the invention.

FIG. 2 is a perspective view of a sputtering chamber 200 according to one embodiment of the invention.

FIG. 3A is a top view of a processing system 300 according to one embodiment of the invention.

FIG. 3B is a side view of the processing system 300 of FIG. 3A.

FIG. 4 is a top view of a sputtering system 400 according to another embodiment of the invention.

FIG. 5 is a side view of a sputtering system 500 according to another embodiment of the invention.

FIG. 6A is a cross sectional view of a cathode assembly 600 according to one embodiment of the invention.

FIG. 6B is a cross sectional view of a cathode assembly 650 according to another embodiment of the invention.

FIG. 7 is a graph showing the target erosion profile according to one embodiment of the invention.

FIG. 8 is a graph showing the target erosion profile according to another embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally comprises a PVD system having separate susceptor, cathode, and lid sections in which each section is on a rail that elevates the sections off the ground. The cathode section may comprise a plurality of rotatable cathodes that lie in a plane such that the axis of rotation for the rotary cathodes is perpendicular to the ground. The lid section and the cathode section may be moved on the rails to open the cathode section for servicing. Of the plurality of rotatable cathodes, the cathodes corresponding to the center of the substrate upon which material will be deposited are spaced a greater distance from the substrate than rotatable cathodes corresponding to the edge of the substrate.

The invention is illustratively described below and may be used in a PVD system for processing large area substrates, such as a PVD system, available from AKT®, a subsidiary of Applied Materials, Inc., Santa Clara, Calif. or a TRITON™ vacuum coating system, available from Applied Films, Inc., a subsidiary of Applied Materials, Inc., Santa Clara, Calif. However, it should be understood that the sputtering system may have utility in other system configurations, including those systems configured to process large area round substrates.

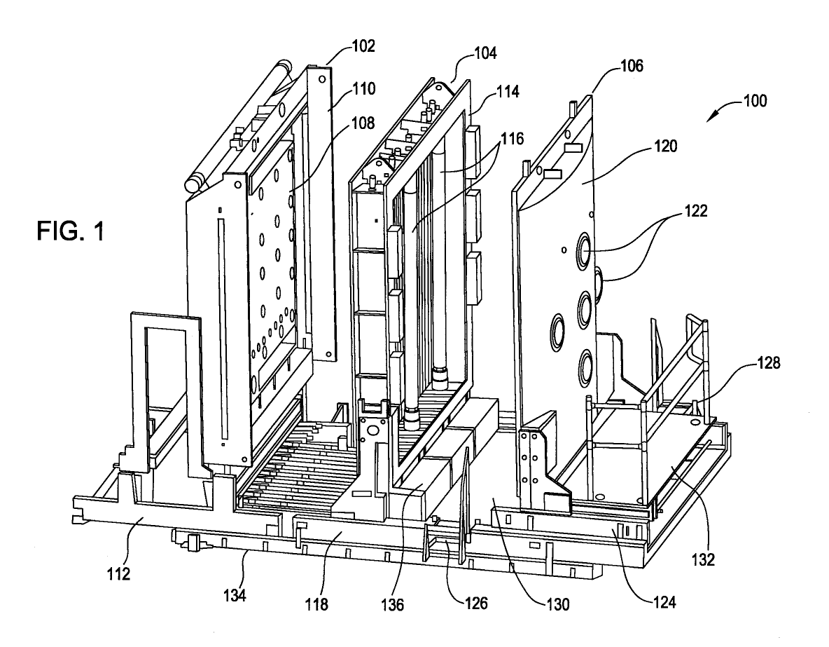

FIG. 1 is a perspective view of a sputtering system 100 according to one embodiment of the invention. The system 100 comprises a susceptor section 102, a cathode section 104, and a lid section 106. A susceptor 108 may be positioned in the susceptor section 102. In one embodiment, the susceptor 108 may be pivotable up to about 90 degrees such that the susceptor moves between a position substantially horizontal to the ground and a position substantially vertical to the ground. In another embodiment, the susceptor 108 may be movable within a plane between a first position and a second position such that the susceptor as a whole moves from a position away from the cathode section 104 to a position closer to the cathode section 104. In yet another embodiment, the susceptor may move by a combination of pivotable movement and movement within a plane.

The susceptor section 102 may comprise a frame 110 and be elevated off of the ground by a rail 112. In the embodiment shown in FIG. 1, the susceptor 108 and the susceptor section 102 are oriented such that they are perpendicular to the ground. The rail 112 supporting the susceptor section 102 may be movable on a track 134 such that the susceptor section can move between a first position and a second position. In one embodiment, the rail 112 is a stationary rail 112 securely fastened to the ground such that the susceptor section 102 and frame 110 remain stationary. It is to be understood that while the susceptor section 102 and the frame 110 may remain stationary, the susceptor 108 may be movable within the susceptor section 102.

The cathode section 104 may comprise a frame 114 and be elevated off of the ground by a rail 118. The rail 118 may be movable along the track 134 such that the cathode section 104 may move and be coupled with the susceptor section 102. Within the cathode section 104, a plurality of rotary cathodes 116 may be present. While two rotary cathodes 116 have been shown in FIG. 1, it is to be understood that more rotary cathodes 116 may be present. Actuators, which function to rotate the rotary cathodes 116, may be positioned in actuator compartments 136 positioned on a platform 126 so that a technician may service the actuators as necessary. In one embodiment, the actuators and hence, the actuator compartments, may be positioned at the top of the cathode section 104. The platform 126 may be accessed by a technician by a staircase 126. The platform 126 allows a technician to inspect and service the interior of the cathode section 104 including the rotary cathodes 116.

The lid section 106 may comprise a lid 120 positioned in a plane perpendicular to the ground. In one embodiment, the lid 120 may be curved. One or more windows 122 may be positioned on the lid 120 so that a technician may view the interior of the system 100 through the lid 120. The lid 120 and windows 122 may be accessed by a technician by a staircase 128 and platform 132. The lid section 106 rests on a rail 124 that elevates the lid off of the ground. The rail 124 rests on the track 134 and may be movable along the track 136 such that the lid section 106 may coupled with the cathode section 104 and decoupled from the cathode section 104 so that the inside of the lid section 120 and the inside of the cathode section 104 may be accessed by a technician.

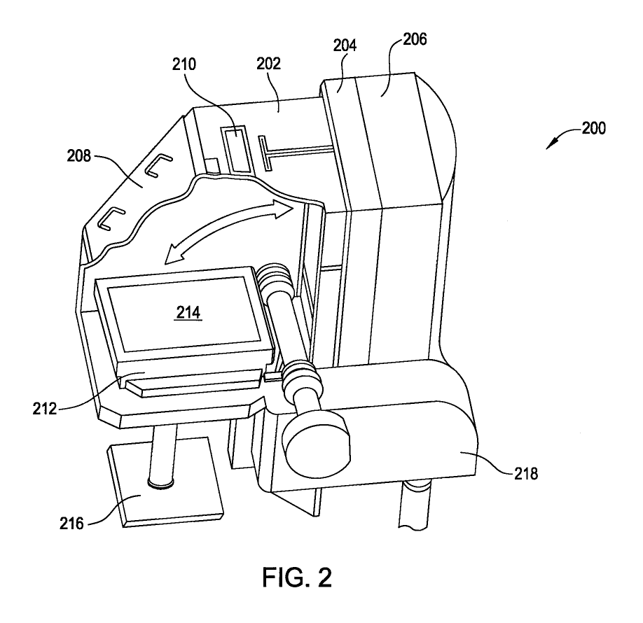

FIG. 2 is a perspective view of a sputtering chamber 200 according to one embodiment of the invention. The sputtering chamber 200 comprises a susceptor section 202, a cathode section 204, and a lid section 206. As may be seen from FIG. 2, the interior of the susceptor section 202 may be accessed by an access panel 208 that is located on the slanted surface. Alternatively, the technician may view the interior of the sputtering chamber 200 through a window 210 located on the top of the susceptor section 202. The susceptor section 202 may be supported by a support pedestal 216.

The susceptor 212 may hold a substrate 214 thereon. The susceptor may rotate up to about 90 degrees so that the side of the substrate 214 that will be coated may move from a position substantially parallel to the ground to a position substantially perpendicular to the ground. The arrows show the movement direction of the susceptor 212 and substrate 214 within the sputtering chamber 200. The susceptor 212 may be moved by an actuator assembly 218.

To process a substrate 214 in the sputtering chamber 200 of FIG. 2, the substrate 214 may initially be provided to the sputtering chamber 200 in the receiving position with the surface upon which material will be deposited lying parallel to the ground. The susceptor 212 then rotates or pivots up to about 90 degrees so that the surface of the substrate 214 upon which material will be deposited on substrate 214 rotates to a processing position that is not parallel with the ground. Once in the processing position, material may be sputter deposited onto the substrate 214. After completion of the sputtering process, the susceptor 212 may then rotate or pivot back to the receiving position. The substrate 214 may then be removed for further processing.

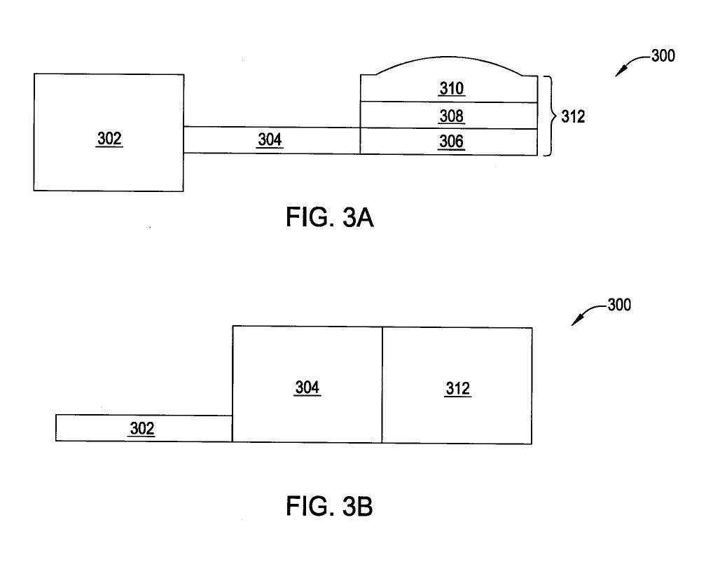

FIG. 3A is a top view of a processing system 300 according to one embodiment of the invention. FIG. 3B is a side view of the processing system 300 of FIG. 3A. Processing system 300 represents an in-line type of processing system wherein a substrate may be moved directly from one chamber to the next chamber without the substrate moving through a common transfer chamber. Processing system 300 comprises a receiving station 302 where a substrate may be initially received. The substrate may be received such that the substrate lies in a plane that is parallel to the ground. The substrate may then be rotated up to about 90 degrees so that the substrate may enter the load station 304. The substrate may then continue through the processing system 300 and be processed at various processing stations. An example of a processing station that may be present is a sputtering chamber 312. The sputtering chamber 312 may comprise a susceptor section 306, a cathode section 308 as described above, and a lid section 310.

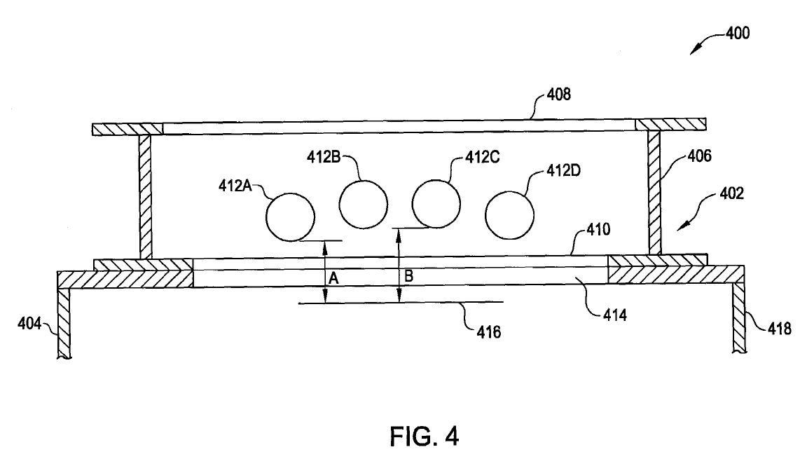

FIG. 4 is a top view of a sputtering system 400 according to another embodiment of the invention. The sputtering system 400 comprises a lid section (not shown), a cathode section 402, and a susceptor section 404. The susceptor section 404 may comprise a frame 418 and house the substrate 416 during processing. The cathode section 402 may also comprise a frame 406. A plurality of rotary cathodes 412A-412D may be positioned within the cathode section 402. While not shown, anodes may be positioned between adjacent cathodes 412A-412D. The cathode section 402 may have an opening 410 on the side facing the corresponding opening 414 located in the susceptor section 404. A second opening 408 may be present in the cathode section 402 on the side of the cathode section 402 that coupled with the lid section (not shown). The lid section, cathode section 402, and susceptor section 404 may be coupled together by conventional coupling means sufficient to ensure that a vacuum may be maintained within the sputtering system 400 under normal operating conditions.

In the embodiment shown in FIG. 4, four rotary cathodes 412A-412D are shown. It is to be understood that more or less rotary cathodes 412A-412D may be positioned within the cathode section 402. In the four cathode embodiment, the two rotary cathodes 412B, 412C that correspond to the center area of the substrate 416 to be coated are spaced a greater distance B from the substrate 416 than the distance A that the rotary cathodes 412A, 412D that correspond to the edge area of the substrate 416 are spaced. The rotary cathodes 412A-412D are thus spaced in an arc-like manner within the cathode section 402. Due to the arc shaped layout of the rotary cathodes 412A-412D, the lid may be curved as discussed above.

During sputtering, the ion density of the plasma formed may have a higher density in the area near cathodes 412B, 412C as compared to the plasma in the area near cathodes 412A, 412D. With an increased ion density, material may be sputtered from the cathodes 412B, 412C at a higher rate. Because of the higher density plasma, the cathodes 412B, 412C may be spaced a greater distance from the substrate 416 to allow the cathodes 412B, 412C to sputter material from the sputtering targets at the same rate as cathodes 412A, 412D. By sputtering at the same rates from each cathode 412A-412D, a film may be uniformly deposited on the substrate 416. In one embodiment, rotary cathodes 412B, 412C may be spaced from the substrate 416 by about 200 mm to about 240 mm while the cathodes 412A, 412D may be spaced about 160 mm to about 200 mm from the substrate 416.

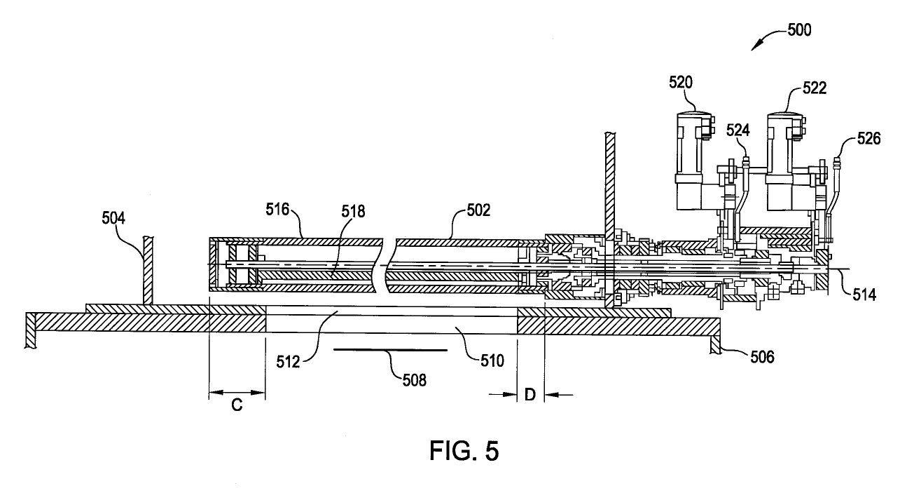

FIG. 5 is a side view of a sputtering system 500 according to another embodiment of the invention. The sputtering system 500 comprises a cathode section and a susceptor section. Both the cathode section and the susceptor sections have frames 504, 506. The cathode section frame 504 has an opening 512 that corresponds to an opening 510 in the frame 506 of the susceptor section. A substrate 508 may be positioned within the susceptor section while a plurality of cathodes 502 may be positioned in the cathode section. The cathodes may be rotary cathodes 502 that rotate about an axis 514. The axis 514 may lie in a plane that is about parallel to the plane of the substrate 508 while also oriented perpendicular to the ground.

The cathodes 502 may each comprise a target 516 having a magnetron 518 within the hollow center of the cathode 502. Both the target 516 and the magnetron 518 may be rotated by separate actuators 520, 522. Additionally, the target 516 may be cooled by a cooling fluid that flows into and out of the target 516 through cooling fluid inlets/outlets 524, 526.

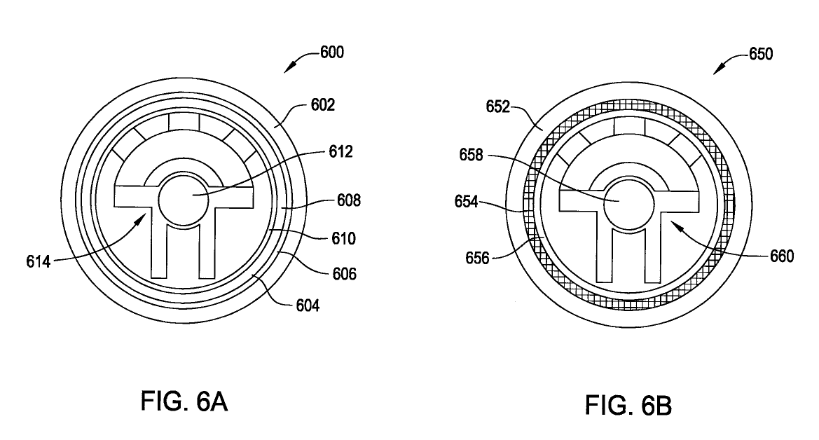

The targets on the rotary cathodes may be bonded to backing tubes or the targets may be monolithic. FIG. 6A is a cross sectional view of a cathode assembly 600 according to one embodiment of the invention. Cathode assembly 600 comprises a target 602 bonded to a backing tube 604 with a bonding layer 606. A magnetron 614 may be positioned within the hollow core of the cathode assembly 600. The magnetron 614 may be rotated. A cooling fluid may cool the cathode assembly 600 by flowing into an area 608 between the backing tube 604 and a magnet cover tube 610. The magnet cover tube 610 prevents the cooling fluid from interfering with the magnetron 614 movement. The cooling fluid exits the cathode assembly 600 by flowing through the area 612 corresponding to the center axis of the cathode assembly 600. By flowing the cooling fluid through the area 608 between the backing tube 604 and the magnet cover tube 610, the cooling fluid at its coolest temperatures (i.e., the temperature when it enters the cathode assembly 600) will be closer to the target 602 than the cooling fluid exiting the cathode assembly 600.

FIG. 6B is a cross sectional view of a cathode assembly 650 according to another embodiment of the invention. Cathode assembly 650 comprises a monolithic sputtering target 652. The monolithic sputtering target may not have a backing tube or a bonding layer. The cooling fluid may flow through the area 654 between the monolithic sputtering target 652 and the magnet cover tube 656 that protects the magnetron 660 from the cooling fluid. The cooling fluid may exit the cathode assembly 650 through the area 658 corresponding to the center axis of the cathode assembly 650.

Rotary cathodes may erode in a uniform manner. By providing a plurality of rotary cathodes spaced from the substrate, each sputtering cathode may have its own individual power supply, actuator for rotation, and magnetron. In one embodiment, a plurality of rotary cathodes may be coupled to a common power supply. The power applied to each rotary cathode may be adjusted and controlled to provide a uniform deposition. Additionally, the rate at which the rotary cathodes rotate may be adjusted to ensure efficient target utilization. By rotating the rotary cathodes, the entire outer surface of the targets may be uniformly eroded. The target material that is sputtered may comprise Al, AlNd, Ti, Mo, MoNb, ITO (Indium Tin Oxide), Zn, ZnO, and combinations thereof.

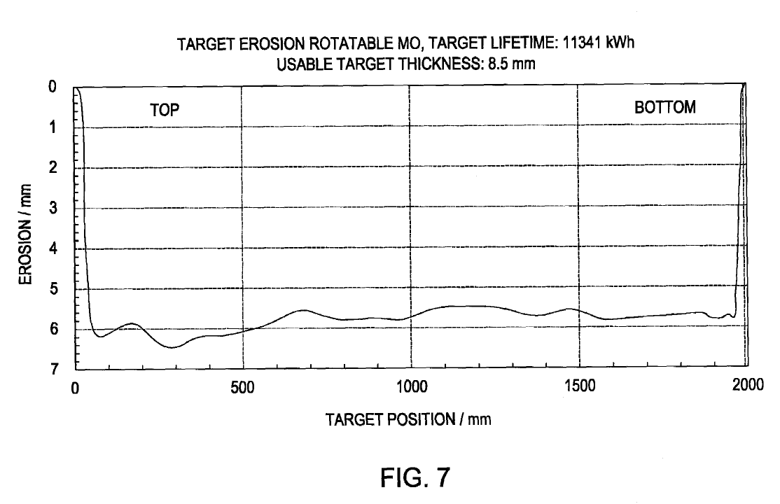

FIG. 7 is a graph showing the target erosion profile according to one embodiment of the invention for a molybdenum sputtering target. FIG. 7 shows that for a rotary molybdenum sputtering target having a usable target thickness of about 8.5 mm, the amount of time that the rotary sputtering target may be used is about 11341 kWh. The target lifetime is a function of target erosion uniformity. The more uniformly that a sputtering target erodes, the longer the lifetime of the sputtering target and hence, the less target material that is wasted. Target erosion uniformity of greater than about 60 percent may be achieved with rotary cathodes. In one embodiment, a target erosion uniformity of about 80 percent may be achieved. In another embodiment, the target erosion uniformity may be about 86 percent. By achieving an erosion uniformity of about 86 percent, the amount of sputtering target material from the target that may be utilized may be about 66 percent.

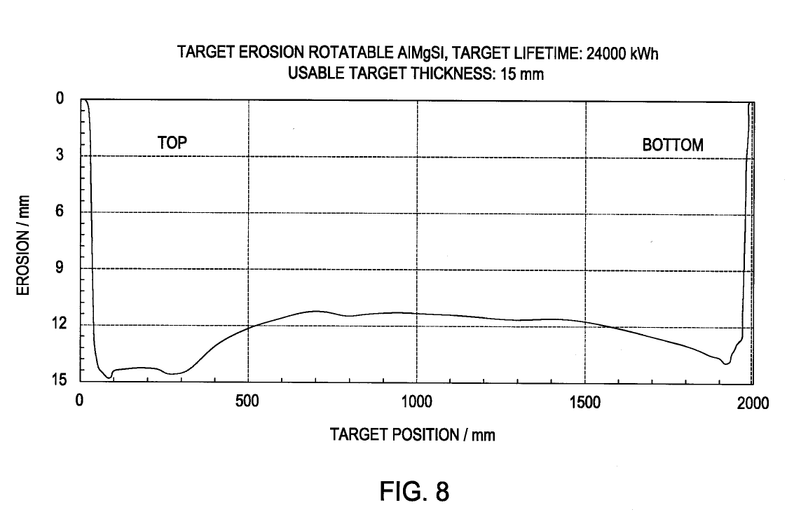

FIG. 8 is a graph showing the target erosion profile according to another embodiment of the invention for an AlMgSi rotary sputtering target. The rotary sputtering target may have a usable sputtering target thickness of about 15 mm. The rotary sputtering target may erode with a uniformity of about 82 percent may be achieved resulting in about a 59 percent sputtering target material utilization.

Rotary cathodes for depositing material onto large area substrates are beneficial because they may provide a uniform deposition of sputtering material onto the substrate. The rotary cathodes may also have a uniform erosion profile to ensure that as much of the sputtering target material as possible is utilized.

While the foregoing is directed to embodiments of the present invention, other and further embodiments of the invention may be devised without departing from the basic scope thereof, and the scope thereof is determined by the claims that follow.

1. An apparatus, comprising:
a sputtering chamber having:
a susceptor section, the susceptor section comprising a susceptor movable between a position oriented substantially parallel to ground and a position substantially perpendicular to the ground;
a cathode section having a plurality of rotary cathodes oriented substantially perpendicular relative to the ground; and
a lid section.

2. The apparatus of claim 1, wherein the cathode section is coupled with a rail such that the cathode section is moveable between a position where the cathode section is coupled with the susceptor section and another position.

3. The apparatus of claim 2, wherein the cathode section rests on the rail such that the cathode section is elevated from the ground.

4. The apparatus of claim 2, wherein the lid section is coupled with a second rail such that the lid section is moveable between a position where the lid section is coupled with the cathode section and another position.

5. The apparatus of claim 1, wherein the plurality of rotary cathodes comprises four rotary cathodes.

6. The apparatus of claim 1, wherein the plurality of rotary cathodes are arranged in an arc pattern such that at least two rotary cathodes are positioned at different distances from the susceptor.

7. The apparatus of claim 1, wherein at least one rotary cathode comprises a monolithic sputtering target assembly.

8. The apparatus of claim 1, wherein at least one of the plurality of rotary cathodes comprises cooling channels.

9. The apparatus of claim 1, wherein at least one of the plurality of rotary cathodes comprises a magnetron movable between a first position and a second position different from the first position.

10. The apparatus of claim 1, wherein the lid section comprises a lid having a substantially non-planar surface oriented substantially perpendicular to the ground.

11. The apparatus of claim 10, wherein the substantially non-planar surface is curved.

12. The apparatus of claim 1, wherein at least one rotary cathode comprises target material comprising at least one material selected from the group consisting of Al, AlNd, Ti, Mo, MoNb, Indium Tin Oxide, Zn, ZnO, and combinations thereof.

13. An apparatus, comprising:
a loading station oriented to receive a substrate oriented substantially perpendicular relative to ground; and
a sputtering chamber, comprising:
a susceptor section having a susceptor;
a cathode section having a plurality of rotary cathodes oriented substantially perpendicular relative to the ground, the cathode section movable between a position coupled with the susceptor section and another position; and
a lid section having a lid, the lid section movable between a position coupled with the cathode section and another position.

14. The apparatus of claim 13, wherein the cathode section rests on a rail such that the cathode section is elevated from the ground.

15. The apparatus of claim 13, wherein the plurality of rotary cathodes comprises four rotary cathodes.

16. The apparatus of claim 13, wherein the plurality of rotary cathodes are arranged in an arc pattern such that at least two rotary cathodes are positioned at different distances away from the susceptor.

17. The apparatus of claim 13, wherein at least one rotary cathode comprises a monolithic sputtering target assembly.

18. The apparatus of claim 17, wherein at least one of the plurality of rotary cathodes comprises cooling channels.

19. The apparatus of claim 13, wherein at least one of the plurality of rotary cathodes comprises a magnetron movable between a first position and a second position different from the first position.

20. The apparatus of claim 13, wherein the lid section comprises a lid having a substantially non-planar surface oriented substantially perpendicular to the ground.

21. The apparatus of claim 20, wherein the substantially non-planar surface is curved.

22. The apparatus of claim 13, wherein at least one rotary cathode comprises target material comprising at least one material selected from the group consisting of Al, AlNd, Ti, Mo, MoNb, Indium Tin Oxide, Zn, ZnO, and combinations thereof.
